(19) United States
(12) Patent Application Publication
(10) Pub. No.: US 2026/0033174 A1
(43) Pub. Date: Jan. 29, 2026

(54) DISPLAY PANEL

(71) Applicant: HKC CORPORATION LIMITED, SHENZHEN (CN)

(72) Inventors: Zhonglin CAO, SHENZHEN (CN); Lidan YE, SHENZHEN (CN)

(73) Assignee: HKC CORPORATION LIMITED, SHENZHEN (CN)

(21) Appl. No.: 19/260,535

(22) Filed: Jul. 6, 2025

(30) Foreign Application Priority Data
Jul. 23, 2024 (CN) 202410999430.2

(51) Int. Cl. H10K 59/127; H10K 59/131

(52) U.S. Cl. CPC H10K 59/1275; H10K 59/131

(57) ABSTRACT

The present application provides a display panel. The display panel may include a glass substrate, a plurality of light-emitting units, a plurality of first bonding portions, and a plurality of silicon-based driving substrates. The glass substrate may include a first surface and a second surface. The glass substrate may include a plurality of conductive vias. The plurality of light-emitting units may be arranged on the first surface of the glass substrate. The plurality of first bonding portions may be arranged on the second surface of the glass substrate. Each of the plurality of first bonding portions may be electrically connected to a matched anode electrode through the conductive via. The plurality of silicon-based driving substrates may be arranged on the second surface of the glass substrate. Each of the plurality of silicon-based driving substrates may be aligned and bonded with at least one first bonding portion.

### CROSS REFERENCE TO RELATED APPLICATIONS

This application claims priority to Chinese Patent Application No. 202410999430.2, entitled “DISPLAY PANEL”, filed on Jul. 23, 2024, which is herein incorporated by reference in its entirety.

### TECHNICAL FIELD

The present disclosure relates to the field of display technologies, and in particular to a display panel.

### BACKGROUND

A monocrystalline silicon driving backplane is a driving substrate formed with semiconductor devices as driving units, and the semiconductor devices are fabricated by the complementary metal oxide semiconductor (CMOS) process. Compared with conventional active-matrix organic light-emitting diode (AMOLED) panels that adopt amorphous silicon, micro-crystalline silicon, or low-temperature poly-silicon thin-film transistors as backplanes, the monocrystalline silicon driving backplane may have a much higher carrier mobility. Therefore, the organic light emitting diode (OLED) display panel based on silicon is currently the type of display panel with the best performance in products of (augmented reality) AR or (virtual reality) VR field.

At present, display chips that are traditionally externally bonded are integrated into the silicon-based driving backplane in silicon-based OLED display panels. A preparation method may include fabricating an OLED light-emitting device by evaporation on a silicon-based driving substrate. The specific process may include: first depositing to form an anode electrode, then fabricating a pixel definition layer, and then depositing an organic light-emitting layer and a cathode electrode in sequence. In this way, pixel units of smaller sizes may be prepared, thereby achieving display fineness beyond a retina level, and the pixel units may include many advantages such as high resolution, high integration, low power consumption, small size, and light weight, or the like.

However, fabricating the OLED light-emitting devices by direct evaporation on the silicon-based driving substrate may easily affect a silicon-based driving circuit, leading to damage of the driving circuit and making it unusable, which may increase the cost. In addition, the maximum size of silicon wafers currently available is only 12 inches. Due to limitation of the silicon wafer size, silicon-based driving may usually only be applied to small-size OLED display panels and may not be applied to large-size OLED display panels.

### SUMMARY

According to a first aspect of the present disclosure, a display panel is provided. The display panel may include a glass substrate, a plurality of light-emitting units, a plurality of first bonding portions, and a plurality of silicon-based driving substrates. The glass substrate may include a first surface and a second surface that are opposite to each other. The glass substrate may include a plurality of conductive vias extending from the first surface to the second surface. The plurality of light-emitting units may be arranged on the first surface of the glass substrate. The light-emitting unit may include an anode electrode, an organic light-emitting layer, and a cathode electrode that are stacked in sequence in a direction away from the glass substrate. The plurality of first bonding portions may be arranged on the second surface of the glass substrate. Each of the plurality of first bonding portions may be electrically connected to a matched anode electrode through the conductive via. The plurality of silicon-based driving substrates may be arranged on the second surface of the glass substrate. Each of the plurality of silicon-based driving substrates may be aligned and bonded with at least one first bonding portion, and may be configured to control the light-emitting unit matching with the at least one first bonding portion.

According to a second aspect of the present disclosure, a display panel is provided. The display panel may include a glass substrate. The glass substrate may include: a first surface and a second surface that are opposite to each other, and a plurality of display regions. In each of the plurality of display regions, the glass substrate may include a plurality of conductive vias extending from the first surface to the second surface. In each of the plurality of display regions, the display panel may further include: a plurality of light-emitting units, a plurality of first bonding portions, and a silicon-based driving substrate. The plurality of light-emitting units may be arranged on the first surface. The light-emitting unit may include an anode electrode, an organic light-emitting layer, and a cathode electrode that are stacked in sequence in a direction away from the glass substrate. The plurality of first bonding portions may be arranged on the second surface. Each of the plurality of first bonding portions may be electrically connected to a matched anode electrode through the conductive via. The silicon-based driving substrate may be arranged on the second surface. The silicon-based driving substrate may include a plurality of first bonding electrodes. The plurality of first bonding electrodes may be aligned and bonded with the plurality of first bonding portions in one-to-one correspondence. In each of the plurality of display regions, each of at least a part of the plurality of first bonding portions may be electrically connected to a matched conductive via through a lead wire. The thickness of the first bonding portion may be greater than that of the lead wire.

According to a third aspect of the present disclosure, a display panel is provided. The display panel may include a glass substrate. The glass substrate may include: a first surface and a second surface that are opposite to each other, and a plurality of display regions. In each of the plurality of display regions, the glass substrate may include a plurality of conductive vias extending from the first surface to the second surface. In each of the plurality of display regions, the display panel further may include: a plurality of light-emitting units, a plurality of first bonding portions, and a silicon-based driving substrate. The plurality of light-emitting units may be arranged on the first surface. The light-emitting unit may include an anode electrode, an organic light-emitting layer, and a cathode electrode that are stacked in sequence in a direction away from the glass substrate. The plurality of first bonding portions may be arranged on the second surface. Each of the plurality of first bonding portions may be electrically connected to a matched anode electrode through the conductive via. The silicon-based driving substrate may be arranged on the second surface. The silicon-based driving substrate may include a display control circuit, a plurality of driving circuits and a plurality of first bonding electrodes. The plurality of first bonding electrodes are aligned and bonded with the plurality of first bonding portions in one-to-one correspondence. The display control circuit may be electrically connected to the plurality of driving circuits. The driving circuit may be electrically connected to the first bonding electrode. The display control circuit may control matched light-emitting units to perform display through the plurality of driving circuits. The display panel further may include a central control circuit electrically connected to the display control circuit in each of the plurality of display regions. The central control circuit may control all of the light-emitting units to perform display through the plurality of silicon-based driving substrates.

### BRIEF DESCRIPTION OF THE DRAWINGS

FIG. 1 is a schematic structural diagram of a first embodiment of a display panel from a first viewing angle according to the present disclosure.

FIG. 2 is a schematic structural diagram of the display panel of FIG. 1 from a second viewing angle.

FIG. 3 is a sectional view along an A-A line of the display panel in FIG. 2.

FIG. 4 is a schematic diagram of a connection of a plurality of silicon-based driving substrates in the display panel in FIG. 2.

FIG. 5 is a sectional view along a B-B line of FIG. 4.

FIG. 6 is a schematic structural diagram of a second embodiment of the display panel from the second viewing angle according to the present disclosure.

FIG. 7 is a sectional view along a C-C line of the display panel in FIG. 6.

FIG. 8 is a schematic structural diagram of a third embodiment of the display panel from the first viewing angle according to the present disclosure.

FIG. 9 is a schematic structural diagram of the display panel of FIG. 8 from the second viewing angle.

FIG. 10 is a sectional view along a D-D line of the display panel in FIG. 9.

FIG. 11 is a sectional view along an E-E line of the display panel in FIG. 9.

FIG. 12 is a schematic structural diagram of a fourth embodiment of the display panel from the second viewing angle according to the present disclosure.

FIG. 13 is a sectional view along an F-F line of the display panel in FIG. 12.

FIG. 14 is a sectional view along a G-G line of the display panel in FIG. 12.

FIG. 15 is a schematic structural diagram of a fifth embodiment of the display panel from the second viewing angle according to the present disclosure.

FIG. 16 is a sectional view along an H-H line of the display panel in FIG. 15.

FIG. 17 is a sectional view of a sixth embodiment of the display panel along an H-H line according to the present disclosure.

FIG. 18 is a sectional view of a seventh embodiment of the display panel along the H-H line according to the present disclosure.

FIG. 19 is a schematic diagram of a connection of a plurality of silicon-based driving substrates of an eighth embodiment of the display panel according to the present disclosure.

### DETAILED DESCRIPTION

Technical solutions in embodiments of the present disclosure will be described clearly and thoroughly in connection with accompanying drawings of the embodiments of the present disclosure. Obviously, the described embodiments are only a part of the embodiments, but not all of them. All other embodiments by a person of ordinary skills in the art based on embodiments of the present disclosure without creative efforts should all be within the protection scope of the present disclosure.

The terms “first”, “second”, and “third” in the present disclosure are only for the purpose of description, and should not be construed as indicating or implying relative importance or implicitly indicating the number of technical features referred to. Therefore, the features defined with “first”, “second”, and “third” may explicitly or implicitly include at least one of the features. In the description of the present disclosure, “a plurality of” means at least two, such as two, three, etc., unless otherwise specifically defined. All directional indicators (such as up, down, left, right, front, back . . . ) in embodiments of the present disclosure are only used to explain a motion state, a relative positional relationship between the components in a specific posture (as illustrated in the drawings). If the specific posture changes, then the directional indication will change accordingly. In addition, the terms “include”, “comprise” and any variations thereof are intended to cover non-exclusive inclusion. For example, a process, a method, a system, a product, or a device that includes a series of operations or units is not limited to the listed operations or units, but optionally includes unlisted operations or units, or optionally also includes other operations or units inherent to these processes, methods, products or devices.

Reference to “embodiments” herein means that a specific feature, structure, or characteristic described in conjunction with the embodiments may be included in at least one embodiment of the present disclosure. The appearance of this phrase in various locations in the specification does not necessarily refer to the same embodiment, nor is it an independent or alternative embodiment mutually exclusive with other embodiments. Those skilled in the art may explicitly and implicitly understand that, the embodiments described herein may be combined with other embodiments.

The present disclosure will be described in detail below with reference to the drawings and embodiments.

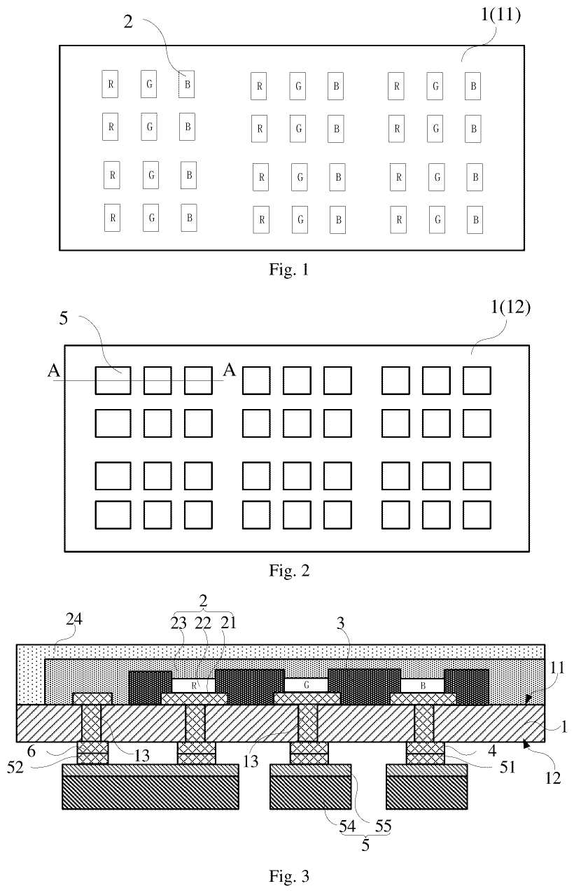

As illustrated in FIG. 1-FIG. 3, FIG. 1 is a schematic structural diagram of a first embodiment of a display panel from a first viewing angle according to the present disclosure, FIG. 2 is a schematic structural diagram of the display panel of FIG. 1 from a second viewing angle, and FIG. 3 is a sectional view along an A-A line of the display panel in FIG. 2. In the present disclosure, the first viewing angle may be a front side, and the second viewing angle may be a back side. The present disclosure provides the display panel. The display panel may be an OLED display panel. The display panel may include a glass substrate 1, a plurality of light-emitting units 2, a plurality of first bonding portions 4, and a plurality of silicon-based driving substrates 5.

The glass substrate 1 may include a first surface 11 and a second surface 12 that are opposite to each other. The glass substrate 1 may include a plurality of conductive vias 13 extending from the first surface 11 to the second surface 12. Specifically, a laser-induced etching technology may be adopted to define through-holes in the glass substrate 1. Then, conductive materials may be filled in the through-holes to form the conductive vias 13. In this way, the opposite first surface 11 and second surface 12 of the glass substrate 1 may achieve electrical connection through the conductive vias 13. The diameter of the conductive vias 13 may range from 50 micrometers to 100 micrometers. If a spacing between adjacent conductive vias 13 is too small, a structural strength of the glass substrate 1 may be affected, and damage to the glass substrate 1 may be caused. If the spacing is too large, the density of the conductive vias 13 may be affected. Therefore, the spacing between adjacent conductive vias 13 may range from 50 micrometers to 150 micrometers.

The plurality of light-emitting units 2 may be arranged on the first surface 11 of the glass substrate 1. The light-emitting unit 2 may include an anode electrode 21, an organic light-emitting layer 22, and a cathode electrode 23 that are stacked in sequence in a direction away from the glass substrate 1. Specifically, a pixel definition layer 3 may also be arranged on the first surface 11 of the glass substrate 1. The pixel definition layer 3 may protrude from the glass substrate 1 and enclose to form a plurality of pixel accommodation regions (not illustrated in the figures). The plurality of light-emitting units 2 may be respectively arranged within the plurality of pixel accommodation regions.

The anode electrodes 21 may be arranged on the surface of the glass substrate 1 exposed through the pixel accommodation regions. The pixel definition layer 3 may cover an edge of the anode electrode 21. This is to avoid a contact between the anode electrodes 21 of adjacent light-emitting units 2, which may cause a case of signal crosstalk. The organic light-emitting layer 22 may be arranged on a side surface of an anode electrode 21 away from the glass substrate 1. The cathode electrode 23 may be arranged on a side of the organic light-emitting layer 22 away from the anode electrode 21, and may cover the organic light-emitting layers 22 of the plurality of light-emitting units 2, so as to form a full-surface of common cathode. The anode electrode 21 may transmit an anode drive signal to the organic light-emitting layer 22, and the cathode electrode 23 may transmit a cathode drive signal to the organic light-emitting layer 22, so as to drive the organic light-emitting layer 22 to emit light.

In some embodiments, the light-emitting units 2 may include light-emitting units with different emission colors, such as red light-emitting units, green light-emitting units, and blue light-emitting units, so as to achieve colorful display. Specifically, the emission color of the light-emitting unit 2 may be determined by the emission color of the organic light-emitting layer 22. Alternatively, in some other embodiments, the light-emitting units 2 may also be light-emitting units of a same color, such as the white color, the red color, the green color, the blue color, or other colors, which may be specifically set according to actual needs. For example, the light-emitting units 2 may be white, gray-scale display may be achieved by controlling a brightness of the light-emitting unit 2. A color resistant layer may also be additionally arranged above the light-emitting units 2 to achieve colorful display. For another example, the light-emitting units 2 are blue, a red quantum dot layer may be additionally arranged above some of the light-emitting units 2, and a green quantum dot layer may be additionally arranged above some of the light-emitting units 2, so as to achieve colorful display.

The plurality of first bonding portions 4 may be arranged on the second surface 12 of the glass substrate 1. Each first bonding portion 4 may be electrically connected to a matched anode electrode 21 through the conductive via 13, so as to transmit the anode drive signal to the matched anode electrode 21 through the conductive via 13. The plurality of silicon-based driving substrates 5 may be arranged on the second surface 12 of the glass substrate 1. Each silicon-based driving substrate 5 may be aligned and bonded with at least one first bonding portion 4, and may be configured to control the light-emitting unit 2 matching with the at least one first bonding portion 4. Specifically, the silicon-based driving substrate 5 may include a monocrystalline silicon base 54 and a driving circuit 55 that are stacked or laminatingly disposed. The driving circuit 55 may be electrically connected to the first bonding portion 4, and may be configured to transmit the anode drive signal to the anode electrode 21. Specifically, the driving circuit 55 may include at least one “3T1C” (3 thin-film transistors and 1 capacitor) structure, so as to achieve independent control of each light-emitting unit 2 and a high-quality image display.

In some embodiments, as illustrated in FIG. 1 and FIG. 2, each first bonding portion 4 may be bonded to a silicon-based driving substrate 5. Different first bonding portions 4 may be bonded to different silicon-based driving substrates 5.

By arranging the light-emitting units 2 and the first bonding portions 4 on the two opposite surfaces of the glass substrate 1 respectively, the plurality of first bonding portions 4 may be in contact and electrically connected to the anode electrodes 21 of the matched light-emitting units 2 through the conductive vias 13. In this way, after the first bonding portions 4 are bonded to the silicon-based driving substrates 5, an electrical coupling between the light-emitting units 2 and the silicon-based driving substrates 5 may be achieved, enabling the silicon-based driving substrates 5 to drive the light-emitting units 2 to emit light.

In this way, the light-emitting units 2 may be bonded to the silicon-based driving substrates 5 after being fabricated on the glass substrate 1. There is no need to directly fabricate the light-emitting units 2 on the silicon-based driving substrates 5, the problem of reduced product yield caused by damage to the pixel driving circuit 55 due to directly fabrication of the light-emitting units 2 on the silicon-based driving substrate 5 may be avoided. Furthermore, by arranging the plurality of silicon-based driving substrates 5 on the second surface 12 of the glass substrate 1, and enabling each silicon-based driving substrate 5 to drive only the matched part of the light-emitting units 2 to emit light, the plurality of silicon-based driving substrates 5 may cooperate to drive the light-emitting units 2 at different positions of the display panel respectively. In this way, the size of the display panel may break through a size limitation of the silicon-based driving substrates 5. Large-size (for example, over 50 inches) silicon-based OLED display panels may be fabricated, so as to achieve large-size OLED display with a high resolution and a high refresh rate.

As illustrated in FIG. 3, in some embodiments, each silicon-based driving substrate 5 may further include a first bonding electrode 51. The first bonding electrode 51 may be configured for alignment and bonding with the matched first bonding portion 4. The anode drive signal of the silicon-based driving substrate 5 may be transmitted to the anode electrode 21 through the first bonding electrode 51, the first bonding portion 4, and the conductive via 13.

The display panel may further include at least one second bonding portion 6. The at least one silicon-based driving substrate 5 may further include a second bonding electrode 52. The second bonding portion 6 may be arranged on the second surface 12 of the glass substrate 1. The second bonding portion 6 may be electrically connected to the cathode electrode 23 within the display region 14 through the conductive via 13. At least one second bonding electrode 52 may be aligned and bonded with the at least one second bonding portion 6. The cathode drive signal of the silicon-based driving substrate 5 may be transmitted to the cathode electrode 23 through the second bonding electrode 52, the second bonding portion 6, and the conductive via 13.

In some embodiments, the display panel may include a plurality of second bonding portions 6 arranged at an edge of the second surface 12. The plurality of silicon-based driving substrates 5 located at the edge of the second surface 12 may each include a second bonding electrode 52. The plurality of second bonding portions 6 may be bonded to the plurality of second bonding electrodes 52 in a one-to-one correspondence. The cathode electrode 23 may extend to an edge position of the first surface 11 of the glass substrate 1, and may be electrically connected to the second bonding portion 6 through the conductive via 13 at the edge. In this way, the silicon-based driving substrates 5 at the edge may transmit the cathode signal to the cathode electrode 23 through the conductive vias 13 at the edge of the display panel, which may effectively reduce a voltage drop and increase a cathode uniformity.

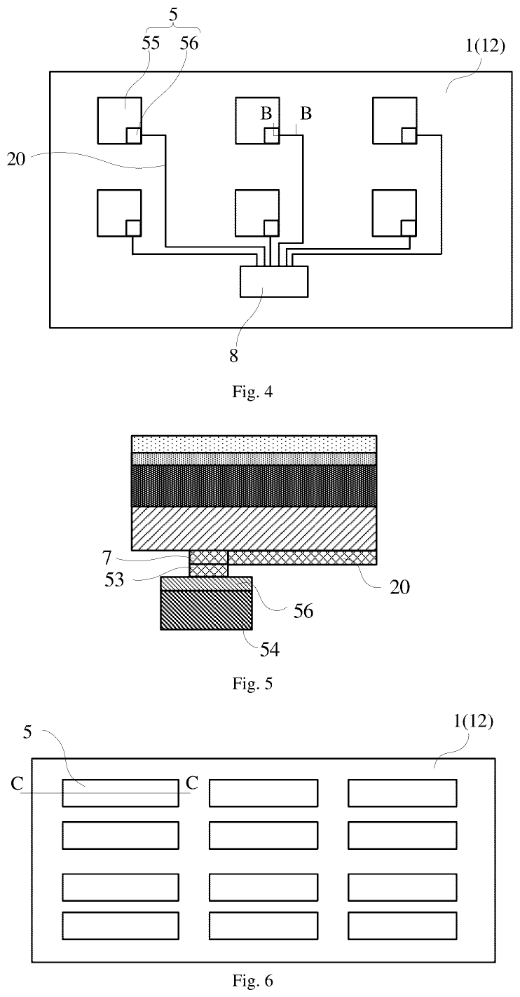

As illustrated in FIGS. 4 and 5, FIG. 4 is a schematic diagram of a connection of the plurality of silicon-based driving substrates in the display panel in FIG. 2, and FIG. 5 is a sectional view along a B-B line of FIG. 4. In some embodiments, each silicon-based driving substrate 5 may include a display control circuit 56. The display control circuit 56 may be electrically connected to the driving circuit 55. The display control circuit 56 may control the matched light-emitting units 2 to perform display through the driving circuit 55. The display control circuit 56 may be an integrated circuit (IC) integrated on the silicon-based driving substrate 5.

The display panel may further include a central control circuit 8. The central control circuit 8 may be electrically connected to the display control circuits 56 of a plurality of silicon-based driving substrates 5. The central control circuit 8 may control all the light-emitting units 2 to perform display through the plurality of silicon-based driving substrates 5, so as to enable the central control circuit 8 to independently control, through a certain silicon-based driving substrate 5, the matched part of the light-emitting units 2 to emit light. The size of the display panel may thus be allowed to break through the size limitation of the silicon-based driving substrate 5. The central control circuit 8 may be arranged on the second surface 12 of the glass substrate 1. Of course, in some embodiments, the display control circuit 56 in one of the silicon-based driving substrates 5 may also be selected as the central control circuit 8.

In the present embodiment, the first bonding electrode 51 may be electrically connected to the driving circuit 55. The display control circuit 56 may transmit the anode drive signal to the first bonding electrode 51 through the driving circuit 55. The second bonding electrode 52 may be electrically connected to the display control circuit 56. The central control circuit 8 may transmit the cathode drive signal to the second bonding electrode 52 through the display control circuit 56. Of course, in some other embodiments, the second bonding electrode 52 may also be directly electrically connected to the central control circuit 8. The central control circuit 8 may directly transmit the cathode drive signal to the second bonding electrode 52.

As illustrated in FIGS. 4 and 5, specifically, a plurality of third bonding portions 7 and a plurality of signal routings 20 may also be arranged on the second surface 12 of the glass substrate 1. Each third bonding portion 7 may be electrically connected to one signal routing 20, and may be electrically connected to the central control circuit 8 through the signal routing 20.

Each silicon-based driving substrate 5 may further include at least one third bonding electrode 53 electrically connected to the display control circuit 56. The third bonding electrode 53 may be aligned and bonded with the third bonding portion 7, so that each display control circuit 56 is electrically connected to the central control circuit 8 through at least one signal routing 20. In this way, the central control circuit 8 may transmit drive signals to any silicon-based driving substrate 5, and the display control circuit 56 on the silicon-based driving substrate 5 may be used by the central control circuit 8 to control the matched light-emitting units 2 to emit light. Specifically, when the display panel is in operation, the central control circuit 8 may transmit, according to address information contained in the drive signal, the drive signal to the display control circuits 56 on the at least one silicon-based driving substrate 5 matching with the address information. After being processed by the display control circuits 56, the drive signal may be transmitted to the matched light-emitting units 2 through the driving circuit 55 on the silicon-based driving substrates 5, so as to drive the matched light-emitting units 2 to emit light.

As illustrated in FIG. 3, additionally, an encapsulation layer 24 may also be arranged on the glass substrate 1. The encapsulation layer 24 may be configured to protect the light-emitting units 2 on the glass substrate 1. Specifically, the encapsulation layer 24 may cover the side surface of the cathode electrode 23 away from the anode electrode 21. The encapsulation layer 24 may engage a surface of the glass substrate 1 that is not covered by the light-emitting units 2.

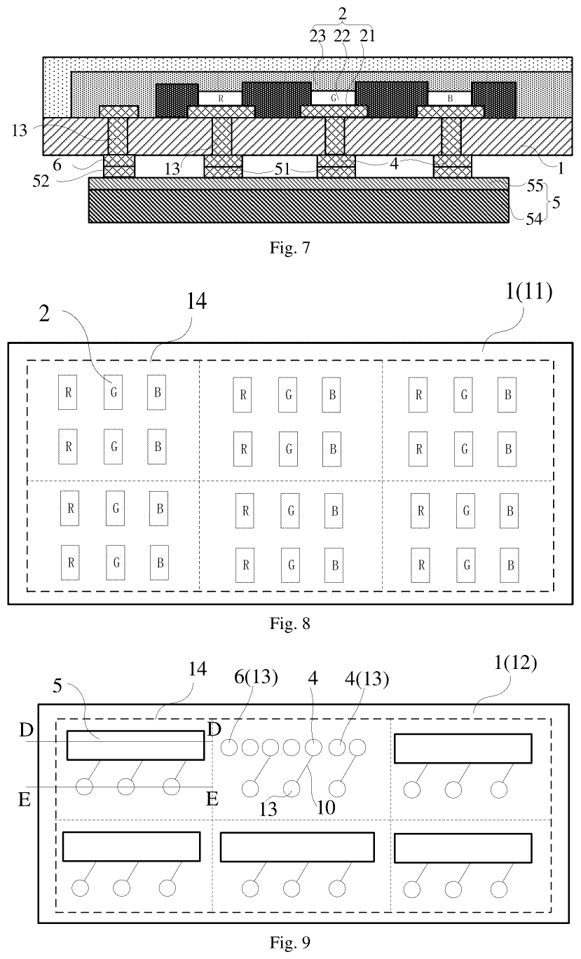

FIG. 6 is a schematic structural diagram of a second embodiment of the display panel from the second viewing angle according to the present disclosure. FIG. 7 is a sectional view along a C-C line of the display panel in FIG. 6. The structure of the display panel provided in the second embodiment of the present disclosure is basically the same as the structure of the display panel provided in the first embodiment of the present disclosure. The difference may lie in the following that: in the second embodiment of the present disclosure, each silicon-based driving substrate 5 may further be bonded to the plurality of first bonding portions 4, so that each silicon-based driving substrate 5 may control the plurality of light-emitting units 2 to emit light. In this way, the number of the silicon-based driving substrates 5 may be decreased, and the manufacturing cost may be effectively reduced. In some embodiments, an example is illustrated in which each silicon-based driving substrate 5 may control three light-emitting units 2 of one pixel unit. For example, the three light-emitting units 2 may include a red light-emitting unit, a green light-emitting unit, and a blue light-emitting unit. Each silicon-based driving substrate 5 may be configured to control the three light-emitting units 2 of different colors in the matched pixel unit to emit light of preset brightness respectively, so that the pixel unit may display light of preset brightness and color.

Specifically, each silicon-based driving substrate 5 may include a plurality of first bonding electrodes 51 and at least one second bonding electrode 52. Each first bonding electrode 51 may be respectively aligned and bonded with one of the plurality of first bonding portions 4 matching with the silicon-based driving substrate 5. The silicon-based driving substrate 5 may transmit anode drive signals to the anode electrodes 21 of the matched plurality of light-emitting units 2 through the plurality of first bonding electrodes 51 respectively. Each silicon-based driving substrate 5 may match with at least one second bonding portion 6. The second bonding portion 6 may be electrically connected to the cathode electrodes 23 of the plurality of light-emitting units 2 matching with the silicon-based driving substrate 5 through the conductive vias 13. The second bonding electrode 52 may be bonded to the second bonding portion 6. The silicon-based driving substrate 5 may transmit cathode drive signals to the matched plurality of light-emitting units 2 through the second bonding electrode 52. The cathode drive signal of each silicon-based driving substrate 5 may be only transmitted to a part of the light-emitting units 2 that matching with the cathode drive signal. In this way, the voltage drop may be further reduced, and the cathode uniformity may be increased.

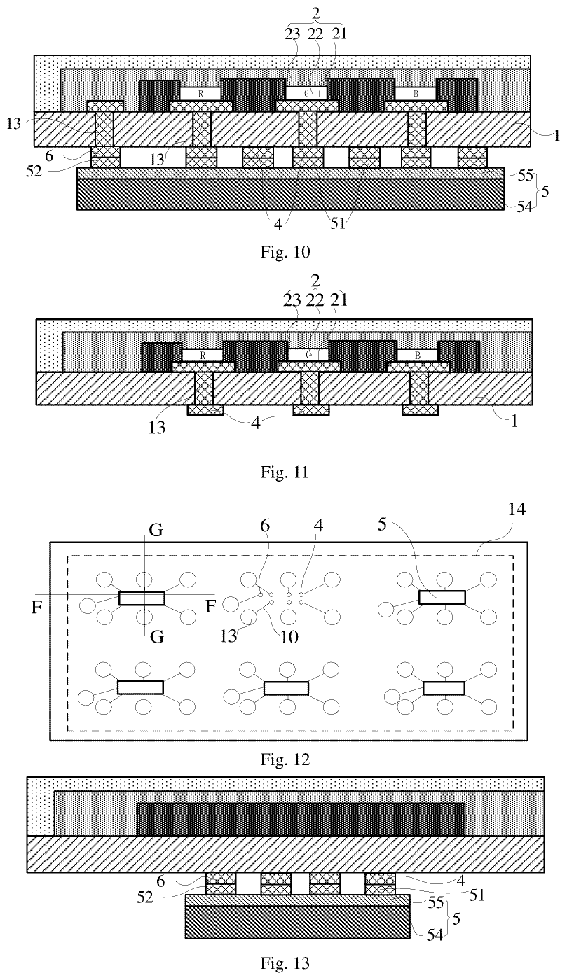

As illustrated in FIG. 8-FIG. 11, FIG. 8 is a schematic structural diagram of a third embodiment of the display panel from the first viewing angle according to the present disclosure, FIG. 9 is a schematic structural diagram of the display panel of FIG. 8 from the second viewing angle, FIG. 10 is a sectional view along a D-D line of the display panel in FIG. 9, and FIG. 11 is a sectional view along an E-E line of the display panel in FIG. 9. The structure of the display panel provided in the third embodiment of the present disclosure is basically the same as the structure of the display panel provided in the first embodiment of the present disclosure. The difference may lie in the following that: in the third embodiment of the present disclosure, the glass substrate 1 may include a plurality of display regions 14. In each display region 14, a plurality of light-emitting units 2, a plurality of first bonding portions 4, and a silicon-based driving substrate 5 may be arranged. A plurality of pixel units may be included within each display region 14. Each silicon-based driving substrate 5 may be configured to control the plurality of pixel units in the matched display region 14 to emit light of preset brightness and color. For example, 6-inch, 8-inch, or 12-inch circular monocrystalline silicon may be used as a base of the silicon-based driving substrate 5. As many driving circuits 55 as possible may be fabricated on the monocrystalline silicon. Each silicon-based driving substrate 5 may match with one display region 14. Each driving circuit 55 may be configured to correspondingly control one light-emitting unit 2 in the display region 14. In this way, the number of silicon-based driving substrates 5 may be further decreased, and the manufacturing cost of the display panel may be further reduced.

As illustrated in FIG. 9-FIG. 11, each silicon-based driving substrate 5 may include a plurality of first bonding electrodes 51. In each display region 14, the plurality of first bonding electrodes 51 of the silicon-based driving substrate 5 are aligned and bonded with the plurality of first bonding portions 4 by one-to-one correspondence. The plurality of first bonding portions 4 may be respectively electrically connected to the anode electrodes 21 of the plurality of light-emitting units 2 in the display region 14 through the plurality of conductive vias 13 in the display region 14. In this way, the silicon-based driving substrate 5 may be enabled to control the matched light-emitting units 2 to emit light through the electrically connected first bonding electrodes 51 and first bonding portions 4.

Specifically, in each display region 14, a part of the plurality of first bonding portions 4 may be misaligned with the matched conductive vias 13, and may be electrically connected to the matched conductive vias 13 through lead wires 10, another part of the first bonding portions 4 may be arranged over the matched conductive vias 13 and cover the conductive vias 13. In the third embodiment of the present disclosure, the plurality of light-emitting units 2 may be arranged in a two-dimensional array in the display region 14. The conductive vias 13 matching with the plurality of light-emitting units 2 may also be arranged in a two-dimensional array. If the first bonding electrodes 51 on the silicon-based driving substrate 5 are directly set in a one-to-one correspondence with the first bonding portions 4 and the conductive vias 13, the first bonding electrodes 51 on the silicon-based driving substrate 5 may also need to be arranged in a two-dimensional array, and the size of the silicon-based driving substrate 5 may need to match that of the display region 14. As mentioned before, in order to ensure the strength of the glass substrate 1, the spacing between adjacent conductive vias 13 should not be too small. Too small spacing may cause waste of the silicon-based driving substrate 5. However, by misalignment between a part of the plurality of first bonding portions 4 and the matched conductive vias 13 and by electrically connecting this part of the plurality of first bonding portions 4 to the matched conductive vias 13 through the lead wires 10, the first bonding electrodes 51 may be arranged on the silicon-based driving substrate 5 in one direction. In this way, the required size of the silicon-based driving substrate 5 may be further decreased, the utilization rate of the silicon-based driving substrate 5 may be effectively increased, and the manufacturing cost may be reduced. Setting the first bonding portions 4 between adjacent conductive vias 13 may not affect the strength of the glass substrate 1.

As illustrated in FIG. 10, at least one second bonding portion 6 may be further arranged in each display region 14. The second bonding portion 6 may be electrically connected to the cathode electrodes 23 in the display region 14 through the conductive vias 13. Each silicon-based driving substrate 5 may further include at least one second bonding electrode 52. At least one second bonding electrode 52 may be aligned and bonded with at least one second bonding portion 6. The silicon-based driving substrate 5 may transmit the cathode drive signal to the cathode electrode 23 in the matched display region 14 through the at least one second bonding electrode 52 and the at least one second bonding portion 6, so as to drive the light-emitting units 2 in the display region 14 to emit light.

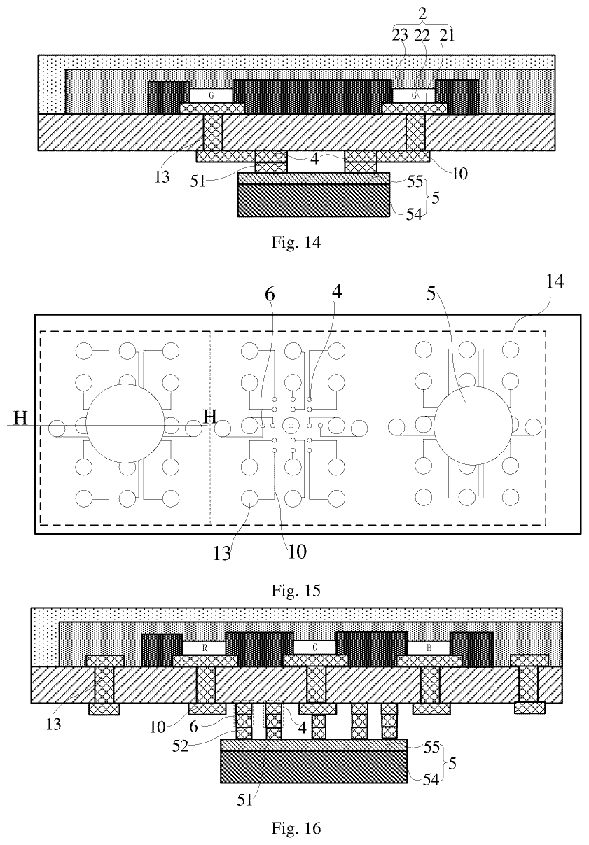

As illustrated in FIG. 12-FIG. 14, FIG. 12 is a schematic structural diagram of a fourth embodiment of the display panel from the second viewing angle according to the present disclosure, FIG. 13 is a sectional view along a F-F line of the display panel in FIG. 12, and FIG. 14 is a sectional view along a G-G line of the display panel in FIG. 12. The structure of the display panel provided in the fourth embodiment of the present disclosure is basically the same as the structure of the display panel provided in the third embodiment of the present disclosure. The difference may lie in the following that: the plurality of first bonding portions 4 in each display region 14 may all be misaligned with the matched conductive vias 13 and may be electrically connected to the matched conductive vias 13 through the lead wires 10. As illustrated in FIG. 12, on the second surface 12, the plurality of conductive vias 13 may be defined on a peripheral outer side of the plurality of first bonding portions 4. The plurality of first bonding electrodes 51 of the silicon-based driving substrate 5 may be bonded to the plurality of first bonding portions 4. In this way, the size of the silicon-based driving substrate 5 may be further decreased, the utilization rate of the silicon-based driving substrate 5 may be further increased, and the manufacturing cost may be further reduced.

Specifically, as illustrated in FIG. 12-FIG. 14, the plurality of first bonding electrodes 51 of each silicon-based driving substrate 5 may be arranged in only two rows. The plurality of first bonding portions 4 in each display region 14 may be arranged in only two rows. The two rows of first bonding electrodes 51 are aligned and bonded with the two rows of first bonding portions 4 by one-to-one correspondence. The silicon-based driving substrate 5 and the plurality of first bonding portions 4 in each display region 14 may only be arranged between two adjacent rows or two adjacent columns of conductive vias 13.

Those skilled in the art should appreciate that: the diameter of the conductive via 13 may usually be 50 micrometers. Considering a structural stability of the glass substrate 1, the spacing between adjacent conductive vias 13 may usually be greater than 50 micrometers. The size of the first bonding electrode 51 on the silicon-based driving substrate 5 may be set to be less than 10 micrometers. If the plurality of first bonding electrodes 51 are directly set in the one-to-one correspondence with the conductive vias 13, a large amount of redundancy in the size of the silicon-based driving substrate 5 may still occur. By setting the lead wires 10 to connect the first bonding portions 4 and the conductive vias 13, and by setting the plurality of first bonding portions 4 in a concentrated manner, the spacing between the plurality of first bonding electrodes 51 may be further reduced. Thus, the size of the silicon-based driving substrate 5 may be further reduced, so as to improve the utilization rate.

In addition, if the lead wires 10 connecting the first bonding portions 4 and the conductive vias 13 are arranged on the glass substrate 1 between adjacent conductive vias 13, there may be a case where the lead wires 10 contact with the first bonding electrodes 51 due to bonding misalignment, resulting in signal crosstalk. By arranging the conductive vias 13 in each display region 14 in only two rows and by arranging the first bonding portions 4 only between two adjacent rows of conductive vias 13, the lead wires 10 may extend outwards. This avoids the lead wires 10 passing between two adjacent conductive vias 13, thus avoiding the case where the lead wires 10 contact with the conductive vias 13 and cause signal crosstalk.

As illustrated in FIG. 15-FIG. 16, FIG. 15 is a schematic structural diagram of a fifth embodiment of the display panel from the second viewing angle according to the present disclosure, and FIG. 16 is a sectional view along an H-H line of the display panel in FIG. 15. The structure of the display panel provided in the fifth embodiment of the present disclosure is basically the same as the structure of the display panel provided in the fourth embodiment of the present disclosure. The difference may lie in the following that: in the fifth embodiment of the present disclosure, the first bonding portion 4 may be electrically connected to the conductive via 13 through the lead wire 10, and the thickness of the first bonding portion 4 may be greater than that of the lead wire 10. In this way, a case may be avoided where the lead wire 10 contacts with the first bonding electrode 51 on the silicon-based driving substrate 5, leading to short-circuit or signal crosstalk, or the like.

Specifically, as illustrated in FIG. 15, on the second surface 12 of the glass substrate 1, the plurality of conductive vias 13 in each display region 14 may be arranged in m rows and n columns (m>2, n>2). The lead wire 10 between the conductive via 13 and the first bonding portion 4 may pass through the gap between the silicon-based driving substrate 5 and the glass substrate 1. If the thickness of the lead wire 10 is the same as that of the first bonding portion 4, the lead wire 10 may contact with the first bonding electrode 51 on the silicon-based driving substrate 5, resulting in cases of short-circuit or signal crosstalk. By configuring the thickness of the first bonding portion 4 greater than that of the lead wire 10, the above-mentioned cases may be avoided, the product yield of the display panel may be increased, and a safety risk of the display panel may also be reduced. Similarly, the thickness of the second bonding portion 6 may also be greater than that of the lead wire 10. In this way, a case may be avoided where the lead wire 10 contacts with the second bonding electrode 52 on the silicon-based driving substrate 5, leading to short-circuit or signal crosstalk, or the like. The first bonding portion 4 may be a multi-layer metal layer or a combined structure of metal thin films and metal thick films, which may facilitate the fabrication of the first bonding portion 4 with a relatively great thickness.

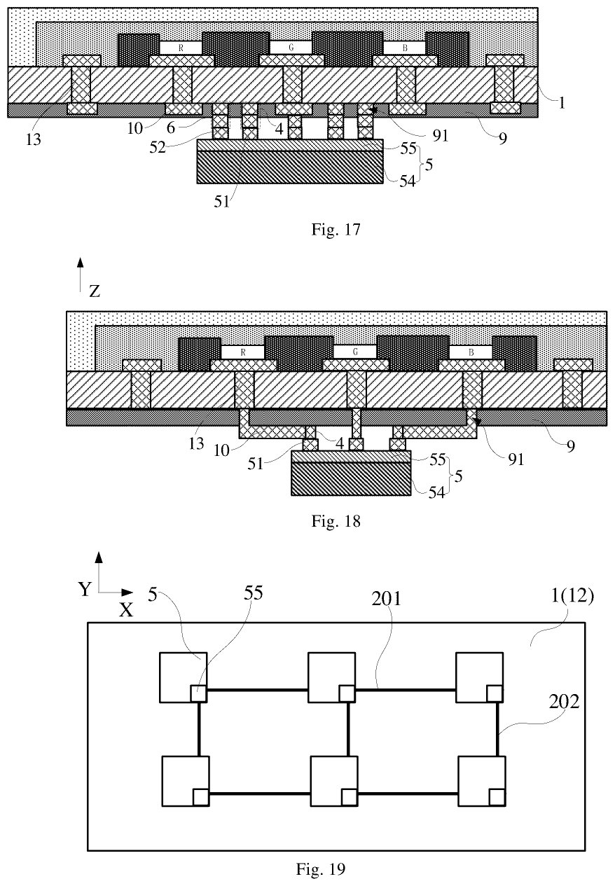

Referring to FIG. 17, FIG. 17 is a sectional view of a sixth embodiment of the display panel along an H-H line according to the present disclosure. The structure of the display panel provided in the sixth embodiment of the present disclosure is basically the same as the structure of the display panel provided in the fifth embodiment of the present disclosure. The difference may lie in the following that: in the sixth embodiment of the present disclosure, an insulation protection layer 9 may also be arranged on the second surface 12 of the glass substrate 1. The insulation protection layer 9 may cover the lead wires 10 and the conductive vias 13, be configured to protect the lead wires 10 and the conductive vias 13, and to avoid the case where the lead wires 10 or the conductive vias 13 contacts with the first bonding electrode 51 or the second bonding electrode 52 on the silicon-based driving substrate, resulting in cases of short-circuit or signal crosstalk, or the like.

Specifically, the insulation protection layer 9 may define an opening 91 matching with the first bonding portion 4. The first bonding portion 4 may be electrically connected to the lead wire 10 through the opening 91, so that the silicon-based driving substrate may transmit the anode drive signal to the light-emitting unit 2 through the first bonding portion 4 and the lead wire 10. The first bonding portion 4 may protrude from the opening 91. In this way, a case may be avoided where the insulation protection layer 9 contacts the first bonding electrode 51 on the silicon-based driving substrate 5, leading to damage.

Referring to FIG. 18, FIG. 18 is a sectional view of a seventh embodiment of the display panel along an H-H line according to the present disclosure. The structure of the display panel provided in the seventh embodiment of the present disclosure is basically the same as the structure of the display panel provided in the sixth embodiment of the present disclosure. The difference may lie in the following that: in the seventh embodiment of the present disclosure, the opening 91 of the insulation protection layer 9 may be defined matching with the conductive via 13 of the glass substrate 1. A first end of the lead wire 10 may extend into the opening 91 and may be electrically connected to the conductive via 13. A second end of the lead wire 10 may be electrically connected to the first bonding portion 4. For each lead wire 10, the second end may be close to the silicon-based driving substrate 5, and the first end may be away from the silicon-based driving substrate 5. In this way, the lead wires 10 may be bundled along the thickness direction Z of the display panel. This may enable the first bonding portion 4 electrically connected to the second end of the lead wires 10 to be arranged more closely. Thus, the size of the silicon-based driving substrate 5 may be decreased, the utilization rate of the silicon-based driving substrate 5 may be further increased, and the manufacturing cost may be reduced.

Referring to FIG. 19, FIG. 19 is a schematic diagram of a connection of the plurality of silicon-based driving substrates of an eighth embodiment of the display panel according to the present disclosure. The structure of the display panel provided in the eighth embodiment of the present disclosure is basically the same as the structure of the display panel provided in the first embodiment of the present disclosure. The difference may lie in the following that: in the eighth embodiment of the present disclosure, a plurality of silicon-based driving substrates 5 may be arranged in a two-dimensional array. The plurality of signal routings 20 may include a plurality of first signal routings 201 and a plurality of second signal routings 202. The plurality of first signal routings 201 may extend along a row direction X. The plurality of second signal routings 202 may extend along a column direction Y. Each first signal routing 201 may connect in series the display control circuits 56 of the plurality of silicon-based driving substrates 5 in the corresponding row. Each second signal routing 202 may connect in series the display control circuits 56 of the plurality of silicon-based driving substrates 5 in the corresponding column. The drive signal may be transmitted through the signal routing 20 to the display control circuit 56 on any silicon-based driving substrate 5. The display control circuit 56 may issue an instruction according to information of the drive signal, so as to transmit the drive signal to the light-emitting units 2 matching with the silicon-based driving substrate 5, or transmit the drive signal to the next silicon-based driving substrate 5. In this way, while ensuring that the central control circuit 8 may transmit signals to the display control circuits 56 on each silicon-based driving substrate 5, the amount of signal routings 20 on the display panel may be decreased, and the manufacturing cost may be further reduced.

The present disclosure provides the display panel. The display panel may include the glass substrate 1, the plurality of light-emitting units 2, the plurality of first bonding portions 4, and the plurality of silicon-based driving substrates 5. The glass substrate 1 may include the first surface 11 and the second surface 12 that are opposite to each other. The glass substrate 1 may define the plurality of conductive vias 13 extending from the first surface 11 to the second surface 12. The plurality of light-emitting units 2 may be arranged on the first surface 11 of the glass substrate 1. Each light-emitting unit 2 may include the anode electrode 21, the organic light-emitting layer 22, and the cathode electrode 23 that are stacked in sequence in the direction away from the glass substrate 1. The plurality of first bonding portions 4 may be arranged on the second surface 12 of the glass substrate 1. Each of the plurality of first bonding portions 4 may be electrically connected to the matched anode electrode 21 through the conductive via 13. The plurality of silicon-based driving substrates 5 may be arranged on the second surface 12 of the glass substrate 1. Each of the plurality of silicon-based driving substrate 5 may be aligned and bonded with at least one first bonding portion 4, and may be configured to control the light-emitting unit 2 matching with the at least one first bonding portion 4. By arranging the light-emitting units 2 and the first bonding portions 4 on the two opposite surfaces of the glass substrate 1 respectively, the plurality of first bonding portions 4 may be in contact and electrically connected to the anode electrodes 21 of the matched light-emitting units 2 through the conductive vias 13. After the first bonding portions 4 are bonded to the silicon-based driving substrates 5, the electrical coupling between the light-emitting units 2 and the silicon-based driving substrates 5 may be achieved, enabling the silicon-based driving substrates 5 to drive the light-emitting units 2 to emit light. In this way, the light-emitting units 2 may be fabricated on the glass substrate 1 and then bonded to the silicon-based driving substrates 5. There is no need to directly fabricate the light-emitting units 2 on the silicon-based driving substrates 5, the problem of reduced product yield caused by damage to the pixel driving circuit 55 due to directly fabrication of the light-emitting units 2 on the silicon-based driving substrates 5 may be avoided. Further, by arranging the plurality of silicon-based driving substrates 5 on the second surface 12 of the glass substrate 1, and enabling each silicon-based driving substrate 5 to drive only the matched part of the light-emitting units 2 to emit light, the plurality of silicon-based driving substrates 5 may cooperate to drive the light-emitting units 2 at different positions of the display panel respectively. In this way, the size of the display panel may break through the size limitation of the silicon-based driving substrates 5. Large-size silicon-based OLED display panels may be fabricated, so as to achieve large-size OLED display with high resolution and high refresh rate.

The above are only implementations of the present disclosure, and do not limit the patent scope of the present disclosure. Any equivalent changes to the structure or processes made by the description and drawings of this application or directly or indirectly used in other related technical field are included in the protection scope of the present disclosure.

1. A display panel, comprising:
a glass substrate, comprising a first surface and a second surface that are opposite to each other, wherein the glass substrate comprises a plurality of conductive vias extending from the first surface to the second surface;
a plurality of light-emitting units, arranged on the first surface of the glass substrate; wherein the light-emitting unit comprises an anode electrode, an organic light-emitting layer, and a cathode electrode that are stacked in sequence in a direction away from the glass substrate;
a plurality of first bonding portions, arranged on the second surface of the glass substrate; wherein each of the plurality of first bonding portions is electrically connected to a matched anode electrode through the conductive via; and
a plurality of silicon-based driving substrates, arranged on the second surface of the glass substrate; wherein each of the plurality of silicon-based driving substrates is aligned and bonded with at least one first bonding portion, and is configured to control the light-emitting unit matching with the at least one first bonding portion.

2. The display panel as claimed in claim 1, wherein
the glass substrate comprises a plurality of display regions; the plurality of light-emitting units, the plurality of first bonding portions, and one of the plurality of silicon-based driving substrates are arranged in each display region; each silicon-based driving substrate comprises a plurality of first bonding electrodes; in each display region, the plurality of first bonding electrodes of the silicon-based driving substrate are aligned and bonded with the plurality of first bonding portions by a one-to-one correspondence.

3. The display panel as claimed in claim 2, wherein
each of the plurality of first bonding portions in each display regions is misaligned with a matched conductive via, and is electrically connected to the matched conductive via through a lead wire; or
a part of the plurality of first bonding portions in each display region are misaligned with matched conductive vias, and are electrically connected to the matched conductive vias through lead wires, and another part of the plurality of first bonding portions are arranged over the matched conductive vias.

4. The display panel as claimed in claim 3, wherein
the plurality of first bonding electrodes of each silicon-based driving substrate are arranged in only two rows, the plurality of first bonding portions in each display region are arranged in only two rows, the two rows of the first bonding electrodes are aligned and bonded with the two rows of the first bonding portions by a one-to-one correspondence;
in each display region, the silicon-based driving substrate and the plurality of first bonding portions are only arranged between two adjacent rows or two adjacent columns of conductive vias.

5. The display panel as claimed in claim 2, wherein
at least one second bonding portion is further arranged in each display region; the second bonding portion is arranged on the second surface of the glass substrate, and is electrically connected to the cathode electrode in the display region through the conductive via;
each silicon-based driving substrate further comprises at least one second bonding electrode; the at least one second bonding electrode is aligned and bonded with the at least one second bonding portion.

6. The display panel as claimed in claim 1, wherein
the first bonding portion is electrically connected to the conductive via through a lead wire, the thickness of the first bonding portion is greater than that of the lead wire.

7. The display panel as claimed in claim 6, wherein
the second surface of the glass substrate is further provided with an insulation protection layer; the insulation protection layer covers the lead wire and the conductive via, and defines an opening matching with the first bonding portion; the first bonding portion protrudes from the opening;
the opening is defined matching with the conductive via; a first end of the lead wire extends into the opening and is electrically connected to the conductive via, a second end of the lead wire is electrically connected to the first bonding portion; and, for each lead wire, the second end is close to the silicon-based driving substrate, the first end is away from the silicon-based driving substrate.

8. The display panel as claimed in claim 1, wherein
each silicon-based driving substrate comprises a display control circuit and a plurality of driving circuits electrically connected to the display control circuit, the display control circuit controls matched light-emitting units to perform display through the plurality of driving circuits;
the display panel further comprises a central control circuit electrically connected to the display control circuit of the plurality of silicon-based driving substrates; the central control circuit controls all of the light-emitting units to perform display through the plurality of silicon-based driving substrates.

9. The display panel as claimed in claim 8, wherein
a plurality of third bonding portions and a plurality of signal routings are further arranged on the second surface of the glass substrate, each of the plurality of third bonding portions is electrically connected to one of the plurality of signal routings;
each silicon-based driving substrate further comprises at least one third bonding electrode electrically connected to the display control circuit, the third bonding electrode is aligned and bonded with the third bonding portion, such that each display control circuit is electrically connected to the central control circuit through at least one signal routing.

10. The display panel as claimed in claim 9, wherein
the plurality of silicon-based driving substrates are arranged in a two-dimensional array; the plurality of signal routings comprises a plurality of first signal routings and a plurality of second signal routings, the plurality of first signal routings extends along a row direction, and the plurality of second signal routings extends along a column direction; each of the plurality of first signal routings connects in series the display control circuits of the plurality of silicon-based driving substrates in the matched row, each of the plurality of second signal routings connects in series the display control circuits of the plurality of silicon-based driving substrates in the matched column.

11. A display panel, comprising:
a glass substrate, comprising: a first surface and a second surface that are opposite to each other, and a plurality of display regions; wherein in each of the plurality of display regions, the glass substrate comprises a plurality of conductive vias extending from the first surface to the second surface;
in each of the plurality of display regions, the display panel further comprises:
a plurality of light-emitting units, arranged on the first surface; wherein the light-emitting unit comprises an anode electrode, an organic light-emitting layer, and a cathode electrode that are stacked in sequence in a direction away from the glass substrate;
a plurality of first bonding portions, arranged on the second surface; wherein each of the plurality of first bonding portions is electrically connected to a matched anode electrode through the conductive via; and
a silicon-based driving substrate, arranged on the second surface; the silicon-based driving substrate comprises a plurality of first bonding electrodes, the plurality of first bonding electrodes are aligned and bonded with the plurality of first bonding portions in one-to-one correspondence;
wherein in each of the plurality of display regions, each of at least a part of the plurality of first bonding portions is electrically connected to a matched conductive via through a lead wire, the thickness of the first bonding portion is greater than that of the lead wire.

12. The display panel as claimed in claim 11, wherein
a size of the first bonding electrode is less than 10 micrometers; and
in each of the plurality of display regions, a spacing between adjacent conductive vias ranges from 50 micrometers to 150 micrometers.

13. The display panel as claimed in claim 12, wherein
the plurality of first bonding electrodes of the silicon-based driving substrate are arranged in one direction.

14. The display panel as claimed in claim 12, wherein
the plurality of the first bonding electrodes of the silicon-based driving substrate are arranged in only two rows;
in each display region, the silicon-based driving substrate and the plurality of first bonding portions are only arranged between two adjacent rows or two adjacent columns of the conductive vias.

15. The display panel as claimed in claim 12, wherein
the second surface of the glass substrate is further provided with an insulation protection layer; the insulation protection layer covers the lead wire and the conductive via, and defines an opening matching with the first bonding portion; the first bonding portion protrudes from the opening;
the opening is defined matching with the conductive via; a first end of the lead wire extends into the opening and is electrically connected to the conductive via, a second end of the lead wire is electrically connected to the first bonding portion; and, for each lead wire, the second end is close to the silicon-based driving substrate, the first end is away from the silicon-based driving substrate.

16. A display panel, comprising:
a glass substrate, comprising: a first surface and a second surface that are opposite to each other, and a plurality of display regions; wherein in each of the plurality of display regions, the glass substrate comprises a plurality of conductive vias extending from the first surface to the second surface;
in each of the plurality of display regions, the display panel further comprises:
a plurality of light-emitting units, arranged on the first surface; wherein the light-emitting unit comprises an anode electrode, an organic light-emitting layer, and a cathode electrode that are stacked in sequence in a direction away from the glass substrate;
a plurality of first bonding portions, arranged on the second surface; wherein each of the plurality of first bonding portions is electrically connected to a matched anode electrode through the conductive via; and
a silicon-based driving substrate, arranged on the second surface; wherein the silicon-based driving substrate comprises a display control circuit, a plurality of driving circuits and a plurality of first bonding electrodes; the plurality of first bonding electrodes are aligned and bonded with the plurality of first bonding portions in one-to-one correspondence; the display control circuit is electrically connected to the plurality of driving circuits; the driving circuit is electrically connected to the first bonding electrode; the display control circuit controls matched light-emitting units to perform display through the plurality of driving circuits;
wherein the display panel further comprises a central control circuit electrically connected to the display control circuit in each of the plurality of display regions; the central control circuit controls all of the light-emitting units to perform display through the plurality of silicon-based driving substrates.

17. The display panel as claimed in claim 16, wherein
the silicon-based driving substrate further comprises a monocrystalline silicon substrate, the monocrystalline silicon substrate and the plurality of driving circuits are stacked with each other.

18. The display panel as claimed in claim 16, wherein
a plurality of third bonding portions and a plurality of signal routings are further arranged on the second surface of the glass substrate, each of the plurality of third bonding portions is electrically connected to one of the plurality of signal routings.

19. The display panel as claimed in claim 18, wherein
each silicon-based driving substrate further comprises at least one third bonding electrode electrically connected to the display control circuit, the third bonding electrode is aligned and bonded with the third bonding portion, such that each display control circuit is electrically connected to the central control circuit through at least one signal routing.

20. The display panel as claimed in claim 19, wherein
the plurality of silicon-based driving substrates are arranged in a two-dimensional array; the plurality of signal routings comprises a plurality of first signal routings and a plurality of second signal routings, the plurality of first signal routings extends along a row direction, and the plurality of second signal routings extends along a column direction; each of the plurality of first signal routings connects in series the display control circuits of the plurality of silicon-based driving substrates in the matched row, each of the plurality of second signal routings connects in series the display control circuits of the plurality of silicon-based driving substrates in the matched column.
